(19) United States
(12) Patent Application Publication
(10) Pub. No.: US 2010/0320521 A1
(43) Pub. Date: Dec. 23, 2010

(54) Semiconductor device

(75) Inventor: Katsuya Izumi, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/801,206

(22) Filed: May 27, 2010

(30) Foreign Application Priority Data
Jun. 19, 2009 (JP) 2009-146179

(51) Int. Cl. H01L 27/108

(52) U.S. Cl. 257/306; 257/E27.084

(57) ABSTRACT

A semiconductor device according to an exemplary embodiment of the present invention includes a memory cell including an information storage portion including a capacitor upper electrode of a DRAM cell and a capacitor lower electrode formed below the upper electrode and an access transistor for controlling access to the information storage portion, a bit-line connected to the access transistor to write or read data to or from the information storage portion, a word line connected to a gate electrode of the access transistor to control the access transistor, and a capacitive element including an upper electrode made from a same layer as a first metal line formed above the capacitor upper electrode and a lower electrode made from a same layer as the capacitor upper electrode, the capacitive element being formed outside an area where the memory cell is formed.

### INCORPORATION BY REFERENCE

This application is based upon and claims the benefit of priority from Japanese patent application No. 2009-146179, filed on Jun. 19, 2009, the disclosure of which is incorporated herein in its entirety by reference.

### BACKGROUND

1. Field of the Invention

The present invention relates to a semiconductor device including both of a DRAM (Dynamic Random Access Memory) circuit and a logic circuit.

2. Description of Related Art

Recently, since the operation of a semiconductor device has become faster, the number of decoupling capacitive elements required to stabilize the high speed operation of the semiconductor device has increased. On the other hand, because the semiconductor device itself has been miniaturized, it becomes more difficult to secure an area for the decoupling capacitive element.

For the sake of a finer design and lower power consumption of the device, a power supply voltage itself within the device has been decreasing. However, according to the interface standards, e.g., standards for the USB (Universal Serial Bus) and the DDR (Double Data Rate), a voltage (3.3 V) determined by the JEDEC must be used. Therefore, the number of cases where different voltages are used between in the internal circuits and the I/O portions of a device has increased.

An electrode structure of the capacitive element which is formed on an area of a logic circuit in the semiconductor device including both of a DRAM circuit and the logic circuit is described below.

FIG. 4 illustrates an example of a parallel plate type capacitive element. In the parallel plate type capacitive element, a first metal line 1 in the upper layer of a capacitor upper electrode of a DRAM cell serves as a lower electrode and a second metal line 2 in the upper electrode serves as the upper electrode, thereby forming the parallel plate type capacitive element. In the recent manufacturing process of the semiconductor device, a Low-K material is used as a material for an interlayer insulating film to form the upper layer of the first metal line 1 in order to reduce a parasitic capacitance. Accordingly, in a case where the parallel plate type capacitive element includes the first metal line 1 and the second metal line 2, the Low-K material is used as a capacitive insulating film.

The Low-K material has a low dielectric constant so that the Low-K material is not suitable for a capacitance. Further, since the Low-K material consumes wiring resources to the second metal line 2, it reduces the flexibility in terms of circuit connection usage, which is the original purpose of the wiring.

In an example of FIG. 5, the capacitive element includes a polysilicon layer 3 as upper electrodes, a well 4 (i.e., a diffusion layer 11) as a lower electrode and gate oxide films 5 as capacitive insulating film, thereby forming the capacitive element. In the example of FIG. 5, since the gate oxide film is used as the capacitive insulating film, the capacitance per unit area becomes larger. However, in the example of FIG. 5, the area, where a transistor is to be formed under normal circumstances, is consumed by the capacitive element. Therefore, no circuit can be formed on the area where the capacitive element is formed.

In an example of FIG. 6, the capacitive element includes a capacitor upper electrode 7 of the DRAM cell as the upper electrode and capacitor lower electrodes 8 of the DRAM cell as the lower electrodes, thereby forming the capacitive element. Japanese Unexamined Patent Application Publication No. 2003-168780 discloses an example in which the DRAM cell itself is used as the capacitive element in a logic area. In this case, since the capacitive element is the DRAM cell itself, the capacitance per unit area is large.

However, a withstand voltage of the capacitor of the DRAM cell is low. Therefore, there is a problem in reliability when the DRAM cell is used as the decoupling capacitive element of the power supply in which a noise having an amplitude larger than the withstand voltage of the capacitor may occur. Needless to say, the withstand voltage of the DRAM cell is too low to be used as the decoupling capacitive element of the power supply for a 3.3 V interface such as a USB.

### SUMMARY

The present inventor has found a following problem. That is, in a case where a capacitive element is formed in a semiconductor device including both of a DRAM circuit and a logic circuit, it is difficult to form a capacitive element that has a sufficient withstand voltage and capacitance while securing an area for forming the circuit.

A first exemplary aspect of the present invention is a semiconductor including a memory cell including an information storage portion including an upper electrode layer and a lower electrode layer formed below the upper electrode layer and an access transistor for controlling access to the information storage portion, a bit-line connected to the access transistor to write or read data to or from the information storage portion, a word line connected to a gate electrode of the access transistor to control the access transistor, and a first capacitive element including a first metal line formed above the upper electrode layer and an electrode layer made from a same layer as the upper electrode, the first capacitive element being formed outside an area where the memory cell is formed.

Accordingly, in the semiconductor device including both of the DRAM unit and the logic unit, the semiconductor device including a parallel plate type capacitive element having a sufficient withstand voltage and capacitance can be provided.

According to the present invention, the semiconductor device including the capacitive element having a sufficient withstand voltage and capacitance can be provided while securing an area for forming a circuit.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a diagram showing a configuration of a semiconductor device according to a first exemplary embodiment;

FIG. 2 is a diagram showing a configuration of a semiconductor device according to a second exemplary embodiment;

FIG. 3 is a diagram showing a configuration of a semiconductor device according to a third exemplary embodiment;

FIG. 4 is a diagram showing a problem to be solved according to the present invention;

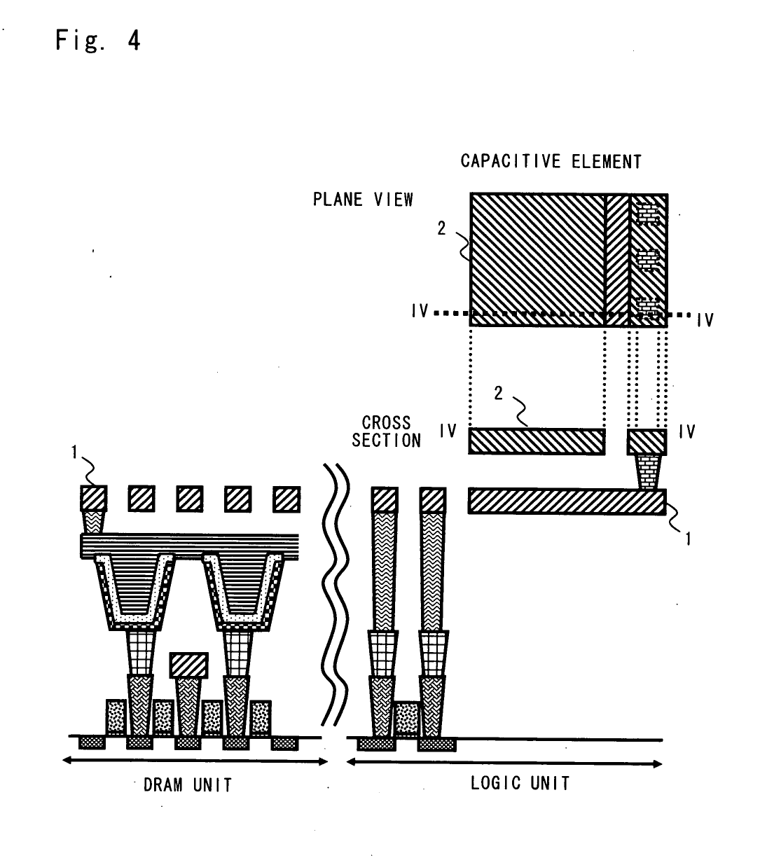

FIG. 5 is a diagram showing a problem to be solved according to the present invention; and

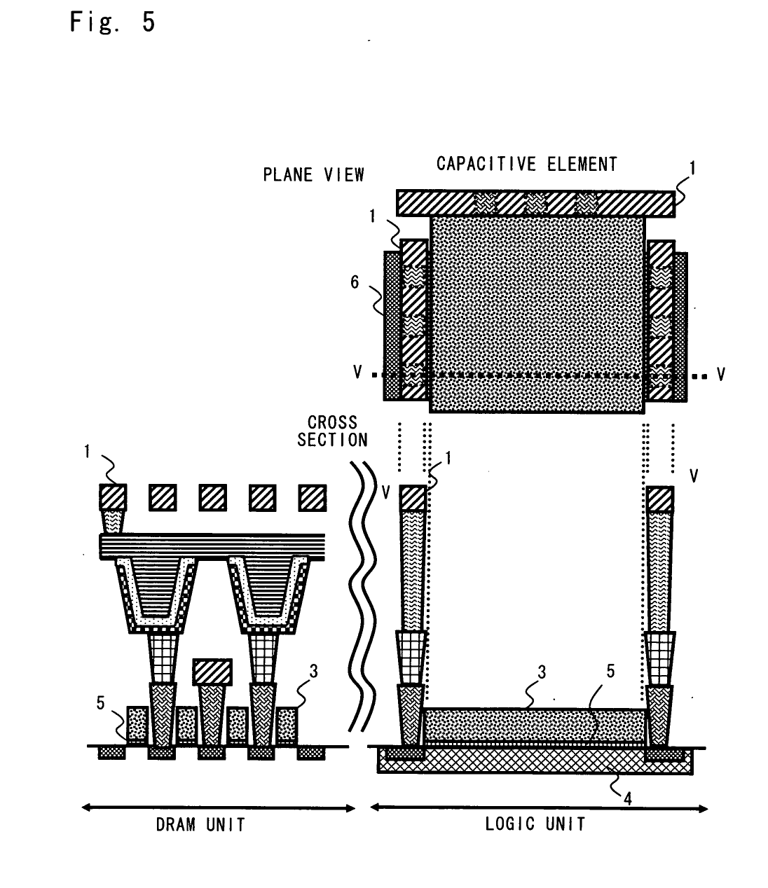

FIG. 6 is a diagram showing a problem to be solved according to the present invention.

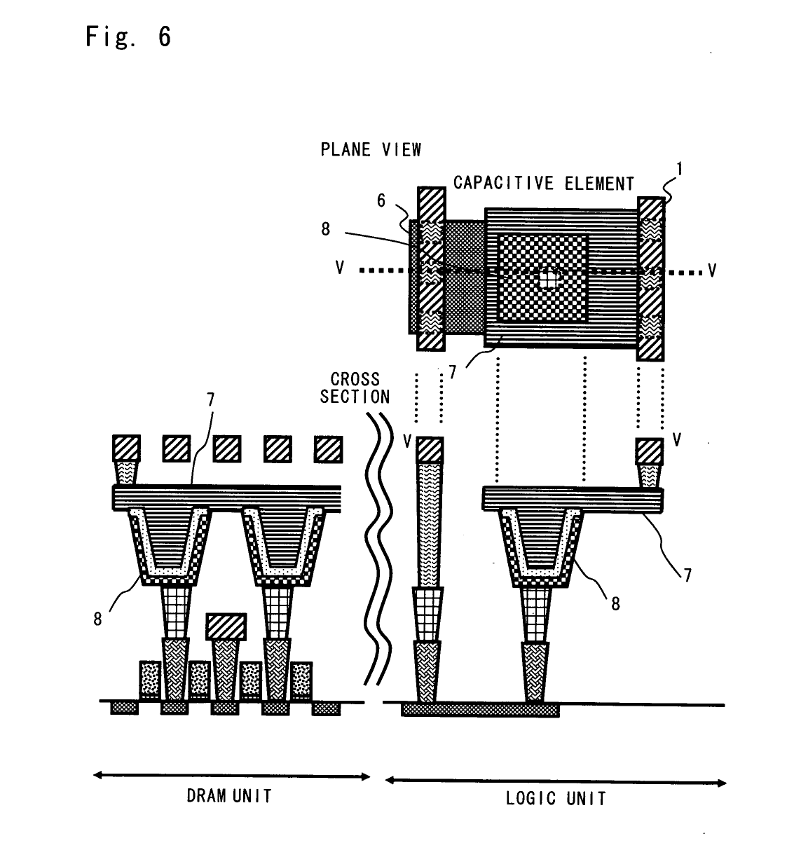

### DETAILED DESCRIPTION OF THE EXEMPLARY EMBODIMENTS

### First Exemplary Embodiment

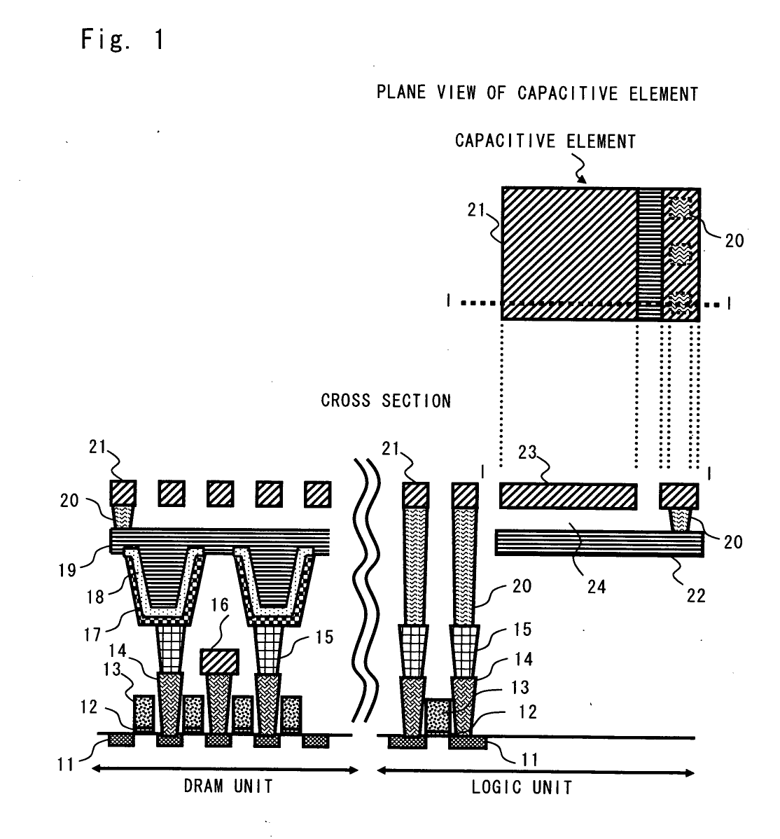

A semiconductor device according to the first exemplary embodiment of the present invention will be described with reference to FIG. 1. FIG. 1 shows a configuration of a semiconductor device according to a first exemplary embodiment. As shown in FIG. 1, the semiconductor device according to the first exemplary embodiment includes both of the DRAM unit and the logic unit.

In FIG. 1, a plane view of a parallel plate type capacitive element is shown on the upper side; a cross section of an area where the capacitive element of the DRAM unit is disposed is shown in a lower left part; and a cross section of an area where the capacitive element of the logic unit is disposed is shown in a lower right part. In the plane view of FIG. 1, components of the lower layers, which cannot be seen in reality, are also illustrated for the sake of explanation.

On the semiconductor substrate, a plurality of diffusion layers 11 are formed at predetermined intervals. On the semiconductor substrate, gate oxide films 12 and gate electrodes 13 are formed so as to be laminated between the diffusion layers 11. The diffusion layers 11 and the gate electrodes 13 of the DRAM unit constitute an access transistor. The access transistor controls access to the information storage portion in a memory cell.

Although it is not shown, a word line is connected to the gate electrode 13 of the access transistor. An application of a control voltage to the gate electrode 13 from the word line turns on the access transistor. Thereby, writing or reading of data to or from the information storage portion, which will be described later, is performed through a bit-line 16. In the cross sections of FIG. 1, element isolation insulating films (for example, STI (Shallow Trench Isolation) and the like) are not shown.

On the diffusion layers 11, a first contact layer 14 is formed. In the DRAM unit of FIG. 1, a second contact layer 15 is formed on the first contact layer 14 disposed on both sides. The first contact layer 14 and the second contact layer 15 connect the DRAM cell to the diffusion layer 11. A bit-line 16 is formed on the first contact layer 14 disposed at the center of the first contact layers 14 of the DRAM unit of FIG. 1. On the second contact layer 15, a DRAM capacitor is formed. The DRAM capacitor includes capacitor lower electrodes 17 of the DRAM cell, a dielectric layer 18 of the DRAM cell and a capacitor upper electrode 19 of the DRAM cell so as to be laminated on the second contact layers 15 in this order. The DRAM capacitor is the information storage portion of the DRAM cell. A third contact layer 20 is formed on the capacitor electrode 19 of the DRAM cell and first metal lines 21 are formed on the third contact layer 20. Although, it is not shown, an interlayer insulating film is interposed between neighboring layers, which are formed according to the respective processes, e.g., between the capacitor upper electrode 19 of the DRAM cell and the first metal line 21.

In the logic unit, the diffusion layer 11, the gate oxide film 12, the gate electrodes 13, the first contact layer 14, the second contact layer 15, the third contact layer 20 and the first metal lines 21 are formed simultaneously with the formation processes of the above described corresponding components.

Now, the parallel plate type capacitive element formed within the logic unit is described below. The capacitive element includes a lower electrode 22 which is an electrode layer formed through the same process as the capacitor upper electrode 19 of the DRAM cell, which is formed through the DRAM cell formation process, and upper electrodes 23 which are an electrode layer formed through the same process as the first metal lines 21, which are formed through the subsequent process. The capacitive element is formed outside an area where the memory cell including the information storage portion and the access transistor is formed. The electrode layer of the capacitor upper electrode 19 which serves as the lower electrode 22 of the capacitive element is formed through a process that is carried out after the process for forming the electrode layer of the bit-line 16.

An interlayer insulation film 24 is interposed between the lower electrode 22 and the upper electrodes 23. The interlayer insulating film 24 is formed simultaneously with the interlayer insulating film interposed between the capacitor upper electrode 19 and the first metal lines 21 of the DRAM cell.

The lower electrode 22 is connected to metal lines formed through the same process as the first metal lines 21, which becomes a different node from the upper electrodes 23 of the capacitive element, through a third contact layer 20 formed at the time of the formation of the DRAM cell. Since the upper electrodes 23 are the first metal lines 21 themselves, the upper electrodes 23 may be also used as the electrodes. Alternatively, the upper electrodes 23 may be connected to a second metal line (not illustrated) which is formed subsequently as required.

In recent manufacturing processes, Low-K material is used for the interlayer insulating film in areas between the first metal lines and the upper layers of the first metal lines for the sake of reducing a parasitic capacitance between lines. To the contrary, the Low-K material is not generally used in layers formed below the first metal lines 21 in order to avoid a problem in strength and heat radiation. Therefore, the interlayer insulating film 24 interposed between the lower electrode 22 and the upper electrodes 23 in accordance with an exemplary aspect of the present invention has a dielectric constant higher than that of the interlayer insulation films disposed above the interlayer insulation film 24.

Further, there is such a tendency that a thickness of the interlayer insulating film between the capacitor upper electrode 19 of the DRAM cell and the first metal lines 21 is made thinner to lower the height of the contact as much as possible or to satisfy similar demands. On the other hand, the interlayer insulating film between the first metal lines 21 and the second metal lines serving as the upper layer of the first metal lines 21 cannot be made thinner in order to avoid an increase of the parasitic capacitance. Consequently, the interlayer insulating film between the capacitor upper electrode 19 of the DRAM cell and the first metal lines 21 is thinner than the interlayer insulating film between the first metal lines 21 and the upper layers disposed above the first metal lines 21.

In the present exemplary embodiment, the interlayer insulating film 24 between the capacitor upper electrode 19 of the DRAM cell and the first metal lines 21 is used as an insulating film for the capacitive element. As described above, the interlayer insulating film 24 has a relatively higher dielectric constant and a film thickness thinner than the other interlayer insulating films. Accordingly, a capacitance per unit area of the capacitive element of the semiconductor device according to the present exemplary embodiment can be increased.

By forming the decoupling capacitive element of FIG. 1, a better noise reduction effect can be expected in the area of the same size. In a case where a necessary capacitance required is determined in advance, the same noise reduction effect can be achieved with a smaller area.

In comparison with the capacitor film of the DRAM cell, the interlayer insulation film 24, which is the capacitive insulating film according to the present exemplary embodiment, is thicker. Accordingly, the withstand voltage of the capacitive element using the interlayer insulation film 24 as a capacitive insulating film in accordance with this exemplary embodiment is higher than that of the capacitive element using a DRAM cell or a gate oxide film. Consequently, the interlayer insulation film 24 can be used as a decoupling capacitive element for a 3.3 V interface system, such as a USB, for which the capacitive element having a configuration of the DRAM cell capacitor cannot be used.

In the present exemplary embodiment, the second metal lines or the like formed as the upper layer of the first metal lines 21 is not used for forming the capacitive element. Accordingly, the second metal lines can be used for wiring of the circuit, which is the original purpose of the second metal. As a result, a remarkable effect can be expected in downsizing the chip size and reducing the number of the wiring layers.

### Second Exemplary Embodiment

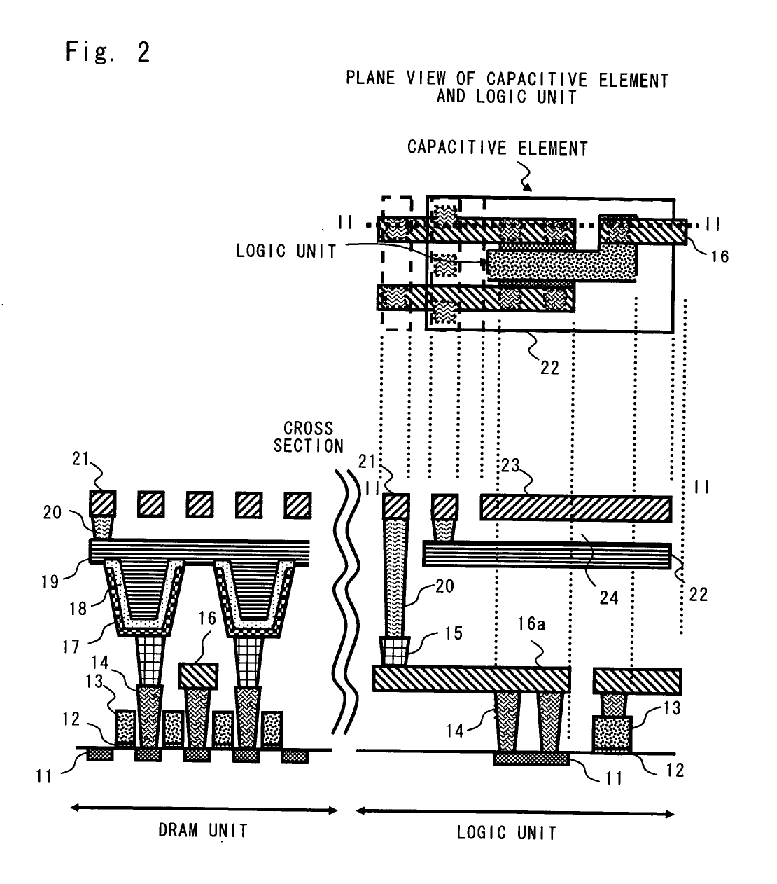

A semiconductor device according to a second exemplary embodiment of the present invention will be described with reference to FIG. 2. FIG. 2 shows a configuration of semiconductor device according to the second exemplary embodiment. In FIG. 2, the same components as those of FIG. 1 are denoted by the same reference symbols, and the description thereof is omitted.

In FIG. 2, a plane view of a parallel plate type capacitive element and a logic unit are shown on the upper side; a cross section of an area where the capacitive element of the DRAM unit is disposed is shown in a lower left part; and a cross section of an area where the capacitive element of the logic unit is disposed is shown in a lower right part. In the plane view of FIG. 2, components of the lower layers, which cannot be seen in reality, are also illustrated for the sake of explanation.

A semiconductor device according to the present exemplary embodiment includes, similarly to the first exemplary embodiment, both of the DRAM unit and the logic unit. Since a configuration of the DRAM unit is identical to that of the first exemplary embodiment, a description thereof is omitted. In the cross sections of FIG. 2, the element isolation insulating films are not illustrated.

As shown in FIG. 2, in the present exemplary embodiment, a circuit using a device element, e.g., a transistor, including the diffusion layer 11, the gate oxide film 12, the gate electrode 13 and the first contact layer 14, and a wiring layer 16a that is formed through a process identical to the bit-line 16 and the like is formed at the same horizontal position as the parallel plate type capacitive element below the capacitive element. The wiring layer 16a made of the same material as the bit-line 16 is used as the wiring layer through which the transistor is connected.

Further, a diffusion layer 11 is connected to the wiring layer 16a through the first contact layers 14. The diffusion layer 11 is used as the source or drain of the transistor. As described above, according to the present exemplary embodiment, the circuit can be formed at the same horizontal position as the capacitive element in the layers below the capacitive element, and thus a remarkable effect in reducing the chip area can be expected.

### Third Exemplary Embodiment

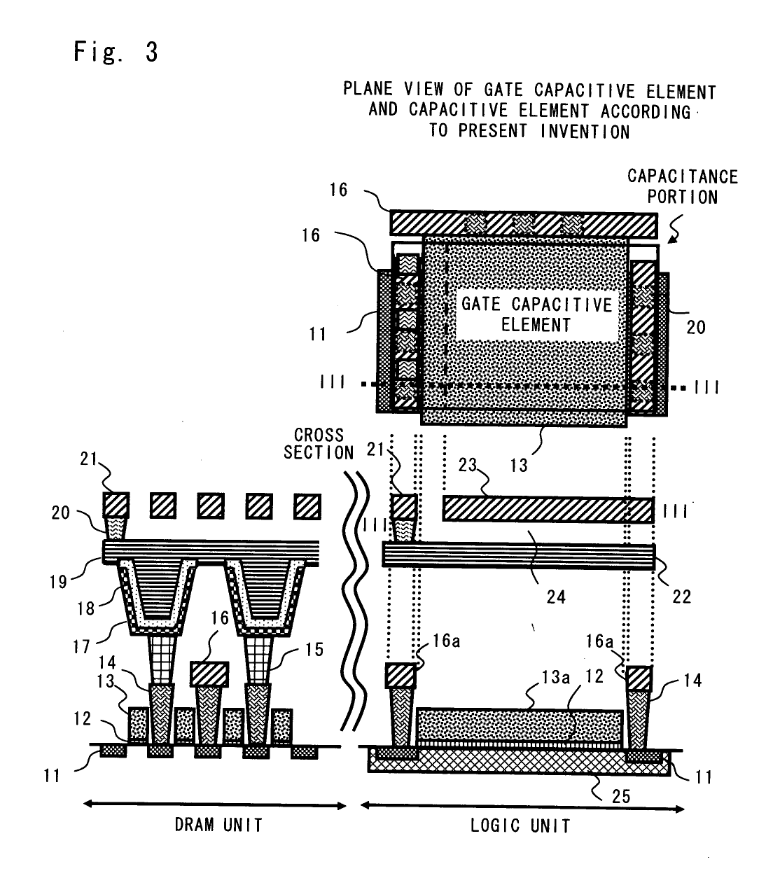

A semiconductor device according to a third exemplary embodiment of the present invention will be described with reference to FIG. 3. FIG. 3 shows a configuration of semiconductor device according to the third exemplary embodiment. In FIG. 3, the same components as those of FIGS. 1 and 2 are denoted by the same reference symbols, and the description thereof is omitted.

In FIG. 3, a plane view of a parallel plate type capacitive element and a gate capacitive element are shown on the upper side; a cross section of an area where the capacitive element of the DRAM unit is disposed is shown in a lower left part; and a cross section of an area where the capacitive element of the logic unit is disposed is shown in a lower right part. In the plane view of FIG. 3, components of the lower layers, which cannot be seen in reality, are also illustrated for the sake of explanation.

In the present exemplary embodiment, at the same horizontal position as the capacitive element including the lower electrode 22 made of the same material as the capacitor upper electrode 19 of the DRAM cell and the upper electrodes 23 made of the same material as the first metal lines 21, a gate capacitive element including the wiring layer 16a made of the same material as the bit-line 16 and the transistor is formed below the capacitive element. More specifically, the gate capacitive element includes the diffusion layer 11, the gate oxide film 12, the electrode layer 13a, the first contact layer 14, the wiring layer 16a and the well 25.

As shown in FIG. 3, in the logic unit, the well 25 is formed on the semiconductor substrate. Two diffusion layers 11 are provided with a space therebetween within the well 25. On the semiconductor substrate, the gate oxide film 12 and the electrode layer 13a are laminated in succession in this order between the two diffusion layers 11. The electrode layer 13a is made of the same material as the gate electrodes 13 of the access transistor.

The wiring layer 16a made of the same material as the bit-line 16 is connected to the diffusion layer 11 through the first contact layer 14. Therefore, in the logic unit, a MOS (MIS) capacitive element including the diffusion layer 11 connected to the wiring layer 16a and the electrode layer 13b made of the same material as the gate electrodes 13 of the access transistor is formed below the capacitive element including the structure from the capacitor upper electrode 19 to the first metal lines 21 of the DRAM cell.

In a conventional logic LSI system, the MOS capacitive element (MOS capacitor) is formed by connecting the gate electrode of a MOS transistor and the diffusion layer (well potential/substrate potential) to the first metal line. In the present exemplary embodiment, by only using the above described layers up to the first metal lines 21, two capacitive elements e.g., a capacitive element using the gate oxide film 12 as the capacitive insulating film and a capacitive element including the structure from the capacitor upper electrode 19 to the first metal lines 21 of the DRAM cell can be formed. Accordingly, the capacitance can be secured more efficiently.

These two capacities may have the different potentials. As such, it is possible to form the decoupling capacitive element of relatively low voltage with the capacitive elements including the gate oxide film 12, and the decoupling capacitive element of relatively high voltage by the capacitance portion including the structure from the capacitor upper electrode 19 to the first metal lines 21 of the DRAM cell. Accordingly, the effective capacitive element satisfying the needs for a multiple power-supply LSI can be formed.

As described above, according to an exemplary aspect of the present invention, in a semiconductor device including both of the DRAM unit and the logic unit, a parallel plate type capacitive element using a layer made of the same material as the capacitor upper electrode 19 of the DRAM cell as the lower electrode 22 and a layer made of the same material as the first metal lines 21 as the upper electrodes 23 without requiring any additional process. As such, the semiconductor device including the capacitive element, which has the sufficient withstand voltage and capacitance, can be realized while securing an area for forming a circuit.

Further, a circuit including a transistor and/or a MOS capacitive element using the gate oxide film 12 and the like can be formed at the same horizontal positions as the above-described capacitive element. Therefore, a capacitive element, e.g., a parallel plate type capacitive element including metal lines, a MOS capacitive element using a gate oxide film and a capacitive element having a configuration of the DRAM cell capacitor, can be formed depending on the respective suitable uses

The present invention is not limited to the above described exemplary embodiments but can be modified as required without departing from the spirit of the present invention. In the above described exemplary embodiment, the DRAM is exemplified. However, the present invention is applicable to memories having an information storage unit above the gate of the transistor, e.g., FeRAMs, MRAMs and phase-change memories.

The first to third exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor device comprising:
a memory cell including an information storage portion including an upper electrode layer and a lower electrode layer formed below the upper electrode layer and an access transistor for controlling access to the information storage portion;
a bit-line connected to the access transistor to write or read data to or from the information storage portion;
a word line connected to a gate electrode of the access transistor to control the access transistor; and
a first capacitive element including a first metal line formed above the upper electrode layer and an electrode layer made from a same layer as the upper electrode, the first capacitive element being formed outside an area where the memory cell is formed.

2. The semiconductor device according to claim 1, wherein the electrode layer that is made from the same layer as the upper electrode and serves as a lower electrode layer of the first capacitive element is formed in a process carried out after formation of the electrode layer of the bit-line.

3. The semiconductor device according to claim 1, further comprising a transistor formed below the first capacitive element, the transistor including a diffusion layer connected to a wiring layer made from a same layer as a wiring layer of the bit-line, the diffusion layer being used as a source or a drain of the transistor.

4. The semiconductor device according to claim 1, further comprising a second capacitive element formed below the first capacitive element, the second capacitive including a diffusion layer connected to a wiring layer made from a same layer as a wiring layer of the bit line and an electrode layer made from a same layer as a gate electrode of the access transistor.

5. The semiconductor device according to claim 4, wherein a voltage applied between electrodes of the first capacitive element differs from a voltage applied to the second capacitive element.

6. The semiconductor device according to claim 1, wherein the memory cell is one of a DRAM cell, a FeRAM cell and a phase-change memory.
